(19) United States
(12) Patent Application Publication
(10) Pub. No.: US 2011/0007480 A1
(43) Pub. Date: Jan. 13, 2011

(54) CAPACITOR MODULE

(75) Inventor: Akihiko Souda, Kanagawa (JP)

Correspondence Address: EDWARDS ANGELL PALMER & DODGE LLP, P.O. BOX 55874, BOSTON, MA, 02205, US

(73) Assignee: KOMATSU LTD., TOKYO (JP)

(21) Appl. No.: 12/735,928

(22) PCT Filed: Feb. 25, 2009
(86) PCT No.: PCT/JP2009/053424

§ 371 Date: Aug. 26, 2010

(30) Foreign Application Priority Data
Mar. 25, 2008 (JP) 2008-078343

(51) Int. Cl. H05K 7/20

(52) U.S. Cl. 361/728

(57) ABSTRACT

A capacitor module is provided with a plurality of capacitor cells each having a capacitor and a capacitor case provided with a first closed-bottomed screw hole with an opening on a bottom surface for housing the capacitor, a metallic cell-fixing body having a through-hole in communication with the first screw hole to which the capacitor cells are fixed by inserting a cell screw in the through-hole and the first screw hole, an insulator made of a thermally conductive insulating material and provided between the capacitor cells and the cell-fixing body for insulating the capacitor cells from the cell fixing body, and a metallic heat-dissipating body having a second closed-bottomed screw hole in which a cell-fixing body screw is inserted and having a flow passage for causing a cooling medium to flow on a rear surface side of a surface on which the second screw hole is provided.

### TECHNICAL FIELD

The invention relates to a capacitor module provided with a plurality of capacitor cells each of which houses a capacitor.

### BACKGROUND ART

A hybrid vehicle equipped with an engine and a generator motor as driving sources is provided with a storage device for storing electricity generated by the generator motor driven by the engine. The storage device also has a function as a power supply for supplying electricity to the generator motor. As such storage device, a capacitor module provided with a large-capacity capacitor is sometimes applied.

When applying the capacitor module as the storage device of a hybrid construction machine as an example of the hybrid vehicle, since the construction machine frequently repeats drive and deceleration every few seconds to several tens of seconds, variation of load applied to the capacitor is large and an amount of heat generation of the capacitor easily becomes large. Therefore, there is a problem that the capacitor rapidly deteriorates and lifetime of the capacitor is short.

In order to prevent the lifetime of the capacitor from becoming short, it is desirable to maintain a state in which an inner temperature of the capacitor is not higher than a heat proof temperature of the capacitor (for example, 60° C.). Therefore, a mechanism to cool the capacitor by efficiently dissipating heat generated by the capacitor, thereby always maintaining the temperature of the capacitor to be not higher than the heat proof temperature. Under such a circumstance, a technique to make a bottom wall portion of a capacitor case, which houses the capacitor thick and to fix the bottom wall portion to the heat-dissipating body on which a flow passage through which a cooling medium flows is formed, thereby improving cooling performance is disclosed (for example, refer to the Patent Document 1).

Patent Document 1: International Publication No. 07/126082 pamphlet

### DISCLOSURE OF INVENTION

### Problems to be Solved by the Invention

However, in the conventional technique disclosed in the above-described Patent Document 1, the capacitor cells are screwed from a bottom surface side of the heat-dissipating body when fastening the capacitor cells to the heat-dissipating body, so that through-holes as many as the capacitor cells should be formed on the heat-dissipating body, and there is a problem of strength of an entire module including the heat-dissipating body. Also, the flow passage should be designed so as to avoid a plurality of through-holes for fixing the capacitor cells, degree of freedom of flow passage design is low.

The invention is made in view of the above-description, and an object thereof is to provide the capacitor module capable of improving the strength of the entire module and having the high degree of freedom when designing a cooling medium flow passage.

### Means For Solving Problem

According to an aspect of the present invention, a capacitor module includes: a plurality of capacitor cells each having a capacitor and a capacitor case provided with a first closed-bottomed screw hole on a bottom surface for housing the capacitor; a metallic cell-fixing body having a through-hole in communication with the first screw hole to which each of the capacitor cells is fixed by screwing a cell screw for fixing each of the capacitor cells into the first screw hole through the through-hole; an insulator being made of a thermally conductive insulating material and installed between the capacitor cells and the cell-fixing body for insulating the capacitor cells from the cell-fixing body; a metallic heat-dissipating body having a second closed-bottomed screw hole in which a cell-fixing body screw for fixing the cell-fixing body is screwed and having a flow passage for causing a cooling medium to flow on a rear surface side of a surface on which the second screw hole is provided; and a cover for covering the surface of the heat-dissipating body on which the flow passage is provided.

Advantageously, in the capacitor module, the number of the second screw hole is smaller than the number of the capacitor cells.

Advantageously, in the capacitor module, the cell-fixing body is a plurality of metallic plates each having a planar shape, and the insulator is a plurality of insulating sheets each of which is thinner than the metallic plates and of which number is the same as or larger than the number of the metallic plates.

Advantageously, in the capacitor module, each of the insulating sheets has a planar portion interposed between the capacitor cells and the metallic plates, and a side surface portion arranged between the capacitor cells and the cell-fixing body screw from both ends in a longitudinal direction of the planar portion along side surfaces of the capacitor cells.

Advantageously, in the capacitor module, the heat-dissipating body has a planar base portion provided with the second screw hole and the flow passage, and a side wall portion installed so as to be substantially orthogonal to the base portion from a peripheral edge of a surface of the base portion provided with the second screw hole to enclose the side surfaces of the capacitor cells.

Advantageously, the capacitor module includes a screw insulator installed between the cell screw and the cell-fixing body for insulating the cell screw from the cell-fixing body.

### Effect of the Invention

According to the invention, since the second closed-bottomed screw hole is provided on the surface different from the surface on which the flow passage for causing the cooling medium to flow is formed of the surfaces of the heat-dissipating body for screwing the cell-fixing body for fixing the capacitor cells to the heat-dissipating body, the strength of the heat-dissipating body may be improved as compared to a case in which the through hole is formed on the heat-dissipating body. Also, since the second screw hole does not pass through the heat-dissipating body, limitation regarding the shape of the flow passage is less as compared to a case in which the second screw hole passes through the heat-dissipating body. Therefore, the capacitor module capable of improving the strength of the entire module and having the high degree of freedom when designing the cooling medium flow passage may be provided.

### BRIEF DESCRIPTION OF THE DRAWINGS

FIG. 1 is an exploded perspective view illustrating a configuration of a capacitor module according to one embodiment of the invention;

FIG. 2 is a view illustrating a schematic configuration of a bottom of a casing of the capacitor module according to one embodiment of the invention;

FIG. 3 is a partial cross-sectional view of a substantial part of the capacitor module seen in a cross-sectional surface parallel to a longitudinal direction of the capacitor module according to one embodiment of the invention;

FIG. 4 is a partial cross-sectional view of the substantial part of the capacitor module seen in a cross-sectional surface parallel to a lateral direction of the capacitor module according to one embodiment of the invention;

FIG. 5 is an exploded perspective view illustrating a peripheral configuration of a capacitor cell;

FIG. 6 is a partial cross-sectional view illustrating an inner configuration of the capacitor cell;

FIG. 7 is a view illustrating an overview of attachment of a plate to which the capacitor cell and insulating sheet are fixed to a heat-dissipating body;

FIG. 8 is a view schematically illustrating a connection mode of a plurality of capacitor cells through a bus bar; and

FIG. 9 is a view illustrating a schematic configuration of a hybrid construction machine to which the capacitor module according to one embodiment of the invention is applied.

### EXPLANATION OF LETTERS OR NUMERALS

1 capacitor module

2 capacitor cell

3 metallic plate

4 insulating sheet

5 heat-dissipating body

6 cover

7, 9 gasket

8 lid

10 wiring box

11 pump

12 bush

13, 15 washer

14 screw cover

16a, 16b, 16c, 16d bus bar

17 bus bar bracket

18 balance substrate

21 capacitor

22 capacitor case

23 external terminal

24 terminal plate

25 film

31 through-hole

31a large diameter portion

31b small diameter portion

32, 223, 511, 513, 521 screw hole

41 planar portion

42 side surface portion

51 base portion

52 side wall portion

53 inlet

54 outlet

100 hydraulic shovel

101 engine

101a self-propelling unit

101b swing unit

102 generator motor

103, 105 inverter

104 swing motor

106 controller

171 first bracket

172 second bracket

211 inner terminal

221 bottom wall portion

222 side wall portion

301, 302, 303 screw

411 opening

512 flow passage

W wiring

### BEST MODE(S) FOR CARRYING OUT THE INVENTION

Hereinafter, a best mode for carrying out the invention (hereinafter, referred to as an “embodiment”) is described with reference to the attached drawings. Meanwhile, the drawings referred to in a following description are schematic ones, and a dimension, a scale and the like of a material might differ in different drawings.

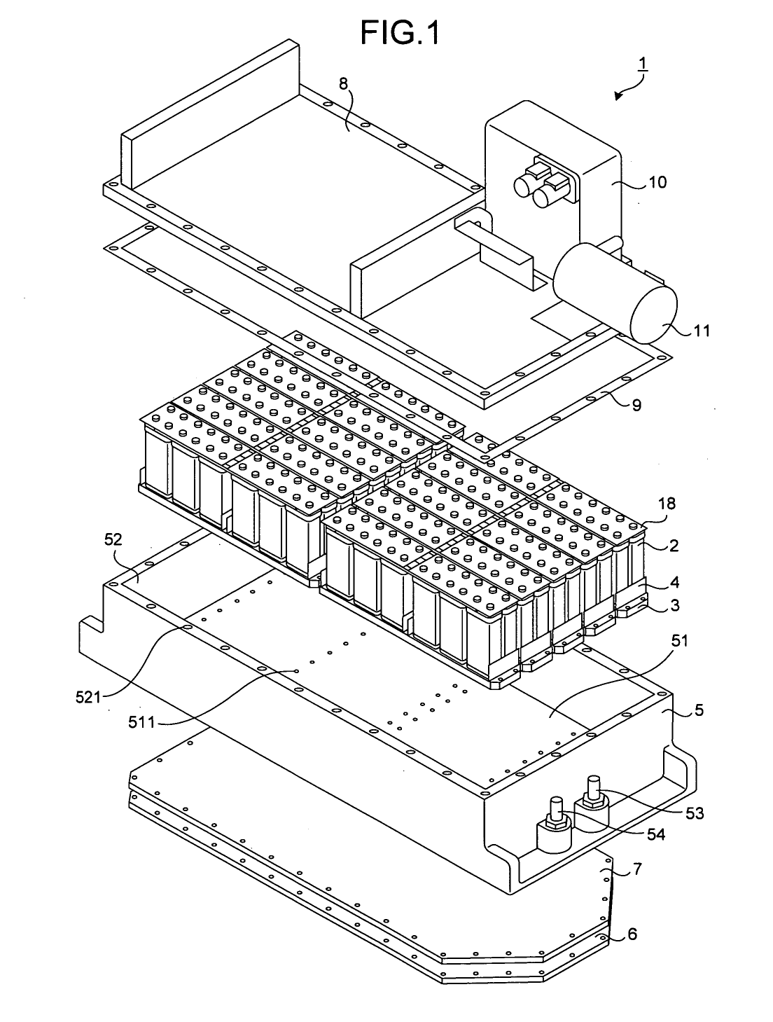

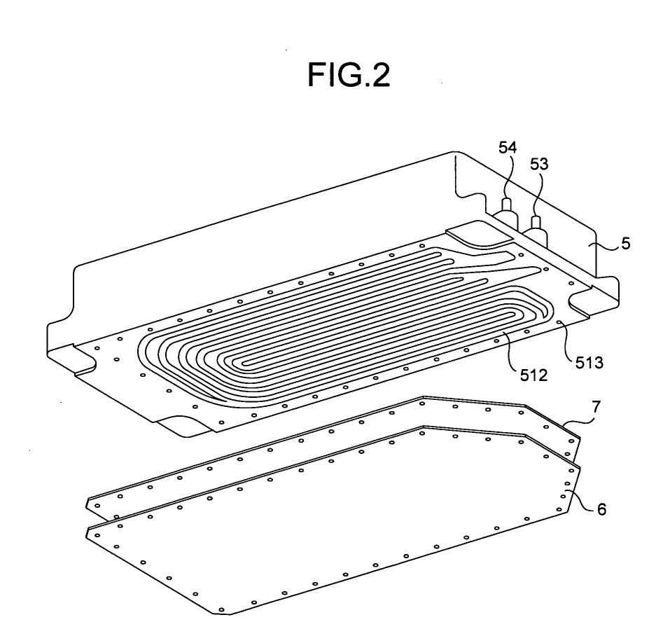

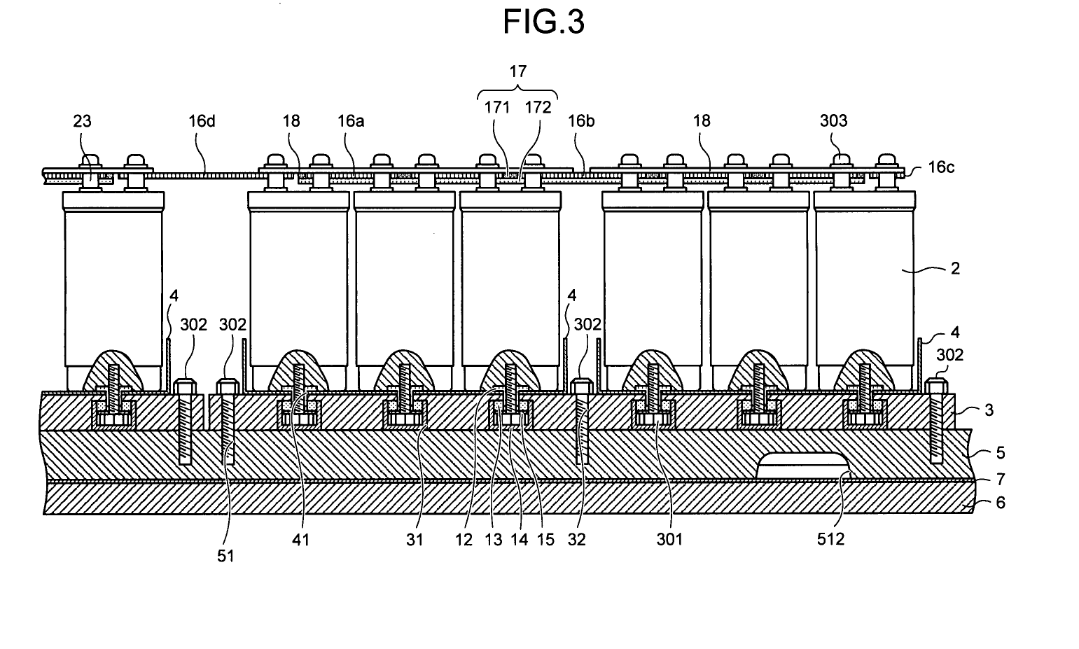

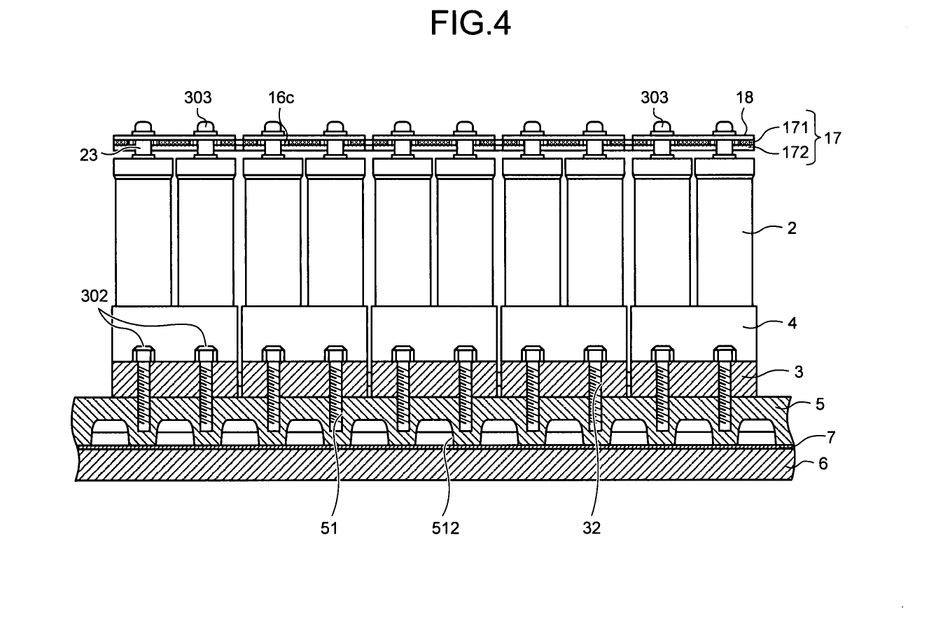

FIG. 1 is an exploded perspective view illustrating a configuration of a capacitor module according to one embodiment of the invention. FIG. 2 is a view illustrating a schematic configuration of a bottom of a casing of the capacitor module according to this embodiment. FIG. 3 is a partial cross-sectional view of a substantial part of the capacitor module seen in a cross-sectional plane parallel to a longitudinal direction of the capacitor module according to this embodiment. FIG. 4 is a partial cross-sectional view of the substantial part of the capacitor module seen in a cross-sectional plane parallel to a lateral direction of the capacitor module according to this embodiment.

A capacitor module 1 illustrated in FIGS. 1 to 4 is provided with a plurality of regularly arranged capacitor cells 2, a plurality of metallic plates 3 for fixing a predetermined number of the capacitor cells 2, an insulating sheet 4 installed between the capacitor cell 2 and the metallic plate 3 for insulating the capacitor cell 2 from the metallic plate 3, a metallic heat-dissipating body 5 for fixing the metallic plate 3 and dissipating heat generated by the capacitor cell 2 on the metallic plate 3, a cover 6 for covering a bottom surface side of the heat-dissipating body 5, a gasket 7 interposed between the heat-dissipating body 5 and the cover 6 for blocking a gap between the heat-dissipating body 5 and the cover 6, a lid 8 attached to the heat-dissipating body 5 for covering an upper surface of the capacitor cell 2, a gasket 9 interposed between an upper end of the heat-dissipating body 5 and the lid 8 for blocking a gap between the upper end of the heat-dissipating body 5 and the lid 8, a wiring box 10 provided with a connector for external connection for housing wiring and the like connected to the capacitor cells 2, and a pump 11 for supplying cooling water (cooling medium) for cooling the capacitor cell 2 to the heat-dissipating body 5.

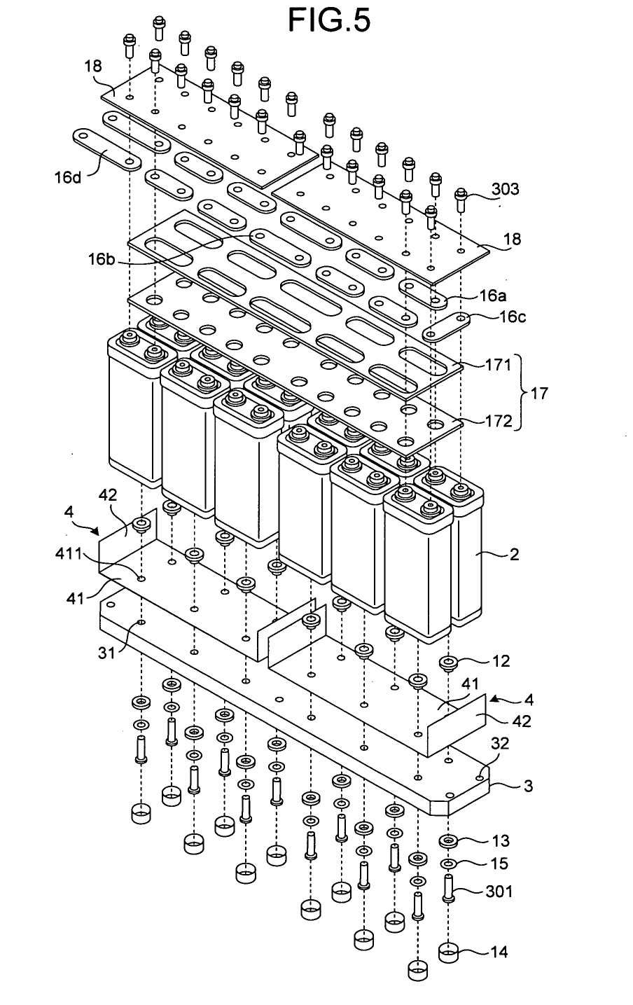

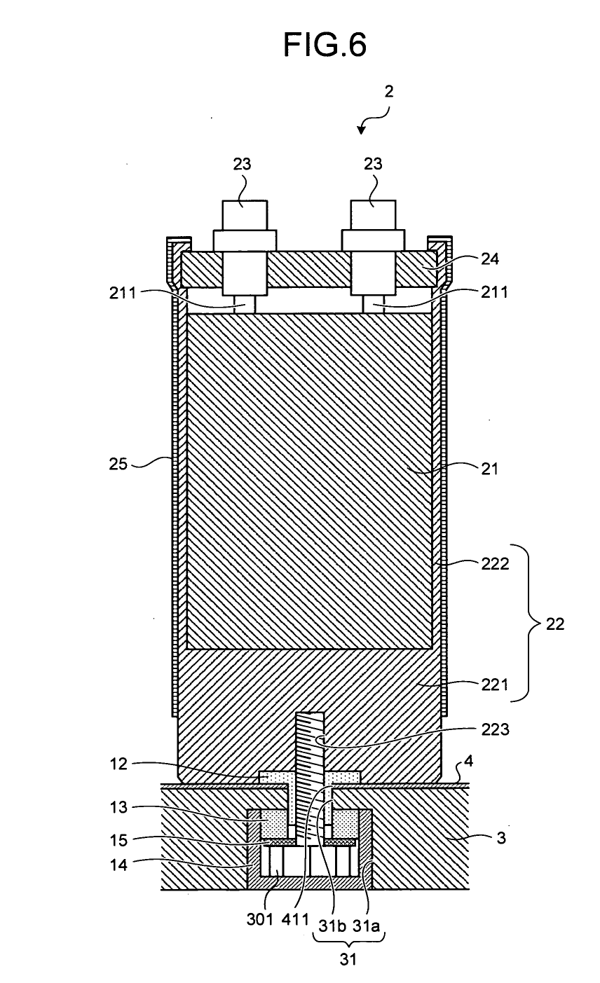

FIG. 5 is an exploded perspective view illustrating a peripheral configuration of the capacitor cell 2. FIG. 6 is a partial cross-sectional view illustrating an inner configuration of the capacitor cell 2. The capacitor cell 2 has a capacitor 21, a capacitor case 22 for housing the capacitor 21, two external terminals 23 connected to the capacitor 21, a terminal plate 24 fixed to the capacitor case 22 in a state of blocking an upper opening of the capacitor case 22 for holding the external terminal 23 and an insulating film 25 for covering an outer periphery of the capacitor case 22. The capacitor 21 has two internal terminals 211 connected to the two external terminals 23, respectively. When voltage is applied from outside to the two external terminals 23, one terminal becomes a positive electrode and the other terminal becomes a negative electrode. An electric double layer capacitor and the like may be applied as such capacitor 21.

The capacitor case 22 is made of metal such as aluminum having relatively excellent thermal conductivity and has a cylindrical shape with one end closed. The capacitor case 22 has a bottom wall portion 221 on which the capacitor 21 is set and a side wall portion 222 extending upward from an outer edge of the bottom wall portion 221. A screw hole 223 (first screw hole) in which a screw 301 (cell screw) for fixing the capacitor cell 2 to the metallic plate 3 is screwed is provided on the center of the bottom wall portion 221. A diameter of the screw hole 223 is expanded in the vicinity of an opening of the bottom wall portion 221, and an end of a bush 12 to be described later is fitted in an expanded diameter portion. A thickness of the bottom wall portion 221 is sufficiently larger than a thickness of the side wall portion 222.

The metallic plate 3 to which the capacitor cell 2 is fixed has a planar shape and has a through-hole 31 passing through the metallic plate 3 in a thickness direction thereof and into which the screw 301 is inserted, and a screw hole 32 passing through the metallic plate 3 in the thickness direction thereof and in which a screw 302 (cell-fixing body screw) for fixing the metallic plate 3 to the heat-dissipating body 5 is screwed. The through-hole 31 has a large diameter portion 31a capable of housing a screw head of the screw 301 and a small diameter portion 31b having a diameter smaller than that of the large diameter portion 31a into which a screw portion of the screw 301 may be inserted. The small diameter portion 31b is in communication with the screw hole 223 of the capacitor cell 2 and an opening 411 provided on the insulating sheet 4 and has a diameter slightly larger than the diameter of the screw hole 223. The metallic plate 3 is made of metal such as aluminum as the capacitor case 22 to which a part (12 in FIG. 5) of the capacitor cells 2 provided on the capacitor module 1 are fixed.

A plurality of screw insulators are installed between the screws 301 and the metallic plate 3 for insulating the screws 301 from the metallic plate 3. Each of a plurality of the screw insulators includes the bush 12 made of resin having a hollow cylindrical shape with a flange formed on one end thereof in which the end with the flange is fitted in the bottom wall portion 221 of the capacitor cell 2 and the other end is inserted into the small diameter portion 31b of the through-hole 31 of the metallic plate 3 and the opening 411 of the insulating sheet 4 and into a hollow portion thereof the screw portion of the screw 301 is inserted, a washer 13 made of resin having a hollow cylindrical shape for holding the end of the bush 12 extending toward the large diameter portion 31a through the small diameter portion 31b of the through-hole 31 of the metallic plate 3 by a hollow portion thereof, and a screw cover 14 made of resin having a closed-bottomed cylindrical shape fitted in the large diameter portion 31a of the through-hole 31 of the metallic plate 3 in a state of housing the screw head of the screw 301 with an opening side sealed by the washer 13. Meanwhile, a metallic washer 15 is installed between the screw 301 and the washer 13.

The insulating sheet 4 has a planar portion 41 interposed between the capacitor cell 2 and the metallic plate 3 and side surface portions 42 arranged between the capacitor cell 2 and the screw 302 from both ends in a longitudinal direction of the planar portion 41 along a side surface of the capacitor cell 2. Six openings 411 each of which is in communication with the screw hole 223 of the capacitor cell 2 and the through-hole 31 of the metallic plate 3 in a state in which the capacitor module 1 is assembled are provided on the planar portion 41. The insulating sheet 4 is formed using a thermally conductive insulating material (such as silicon rubber) and has a function to transmit the heat generated by the capacitor cell 2 to the heat-dissipating body 5 through the metallic plate 3 in addition to a function to insulate the capacitor cell 2 from the metallic plate 3. The insulating sheet 4 insulates a part of (six in FIG. 5) the capacitor cells 2 included in the capacitor module 1 from the metallic plate 3.

The heat-dissipating body 5 has a planar base portion 51 and a side wall portion 52 installed so as to be substantially orthogonal to the base portion 51 from a peripheral edge on a surface of the base portion 51 to enclose the side surfaces of the capacitor cells 2. The heat-dissipating body 5 is made of metal such as aluminum as the metallic plate 3. A closed-bottomed screw hole 511 (second screw hole) in communication with the screw hole 32 of the metallic plate 3 is provided on an upper surface of the base portion 51. Also, a flow passage 512 for causing the cooling water for cooling the capacitor cell 2 to flow and a screw hole 513 for screwing the cover 6 and the gasket 7 is provided on a bottom surface of the base portion 51. On the other hand, a screw hole 521 for screwing the lid 8 and the gasket 9 is provided on an upper surface of the side wall portion 52.

The flow passage 512 has a configuration in which the cooling water flowing from an inlet 53 branches into a plurality of flows to uniformly circulate the bottom surface of the base portion 51 and thereafter join together to reach an outlet 54. A cross-sectional area of the flow passage 512 is substantially uniform regardless of sites, and the flow passage 512 is substantially uniformly arranged on bottoms of all of the capacitor cells 2. Therefore, the cooling water flows smoothly and a similar cooling effect may be exerted to all of the capacitor cells 2. The inlet 53 is connected to the pump 11 through predetermined piping and the outlet 54 is connected to a cooler (not illustrated) for cooling the cooling water, which has circulated the flow passage 512. The cooling water cooled by the cooler reaches again the pump 11 and flows into the flow passage 512. A temperature of the cooling water is adjusted based on a temperature of the capacitor 21. The temperature of the capacitor 21 is detected by a temperature sensor attached to a bus bar on a predetermined position in the capacitor module 1. A controller for controlling the cooler controls the temperature of the cooling water with reference to an output of the temperature sensor.

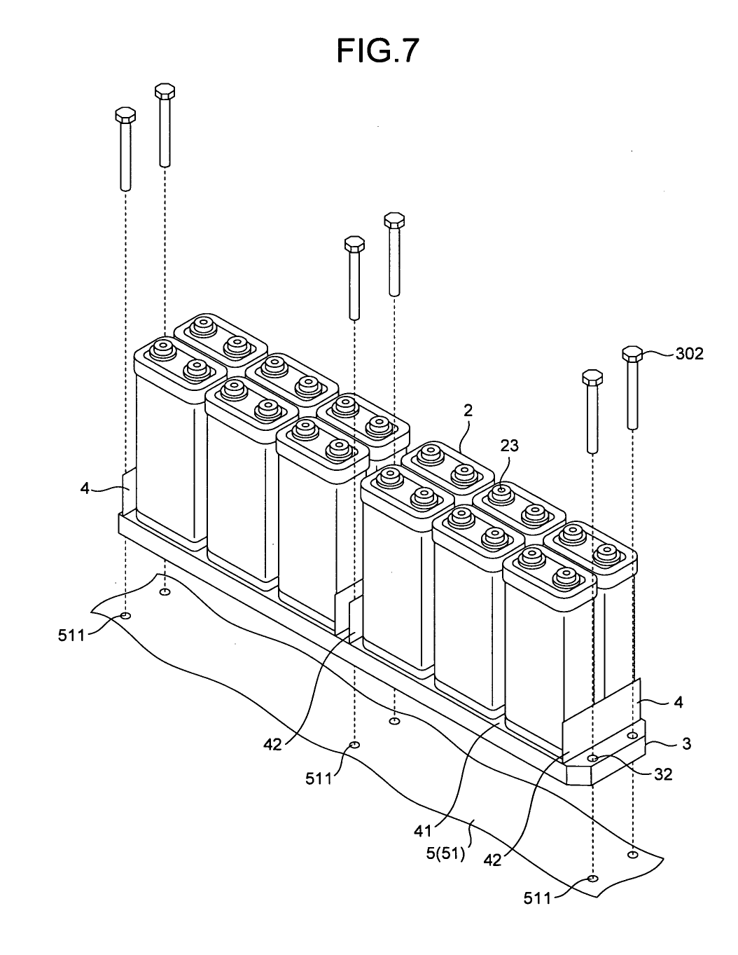

FIG. 7 is a view illustrating an overview of attachment of the metallic plate 3 to which the capacitor cell 2 and the insulating sheet 4 are fixed to the heat-dissipating body 5. The metallic plate 3 and the heat-dissipating body 5 are fixed to each other by screwing the screw 302 in the screw hole 32 of the metallic plate 3 and the screw hole 511 of the heat-dissipating body 5. Two insulating sheets 4 are attached to one metallic plate 3. Therefore, when attaching the metallic plate 3 to which the capacitor cell 2 and the insulating sheet 4 are fixed to the heat-dissipating body 5, the screw 302 screwing in the screw hole 32 located between the side surface portions 42 opposed to each other of the two insulating sheets 4 may be surely prevented from contacting the bottom of the capacitor cell 2.

In the capacitor module 1, two metallic plates 3 are arranged so as to be adjacent to each other in a longitudinal direction of the metallic plate 3 and five metallic plates 3 are arranged so as to be adjacent to each other in a lateral direction of the metallic plate 3, and a total of ten metallic plates 3 are arranged in a matrix pattern. Since 12 capacitor cells 2 are fixed to one metallic plate 3, the capacitor module 1 has 120 capacitor' cells 2.

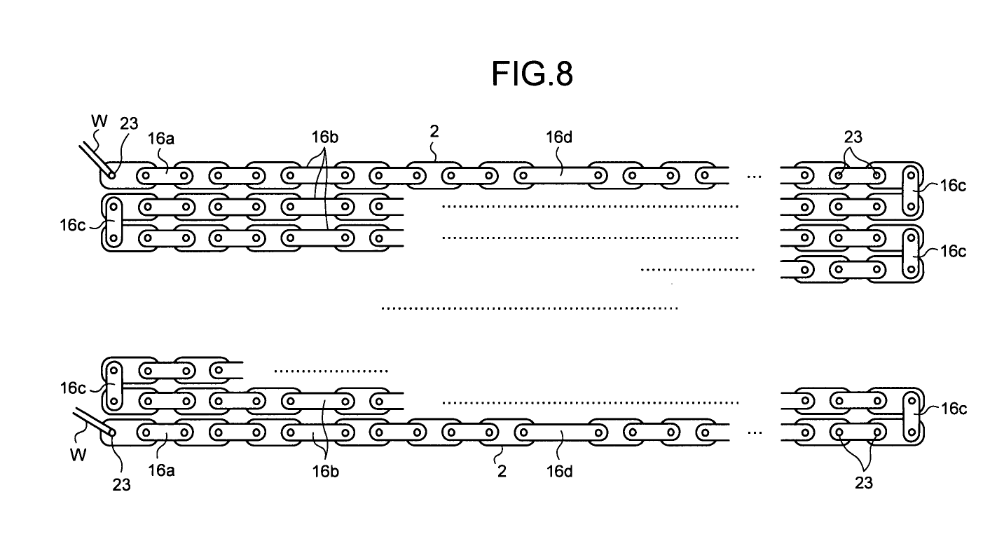

The external terminals 23 of the two capacitor cells 2 adjacent to each other are electrically connected to each other through any of bus bars 16a to 16d made of metal such as copper. FIG. 8 is a schematic diagram of a connection mode of the capacitor cells 2 through the bus bars 16a to 16d. The bus bars 16a to 16d have lengths different to each other according to distances between two external terminals 23, which are coupling targets. The bus bar 16a couples the external terminals 23 of the capacitor cells 2 arranged on the same insulating sheet 4 and adjacent to each other in longitudinal directions thereof. The bus bar 16b couples the external terminals 23 of the capacitor cells 2 attached to the same metallic plate 3 and arranged on the different insulating sheets 4, and adjacent to each other in the longitudinal directions thereof. The bus bar 16c couples the external terminals 23 of the capacitor cells 2 adjacent to each other in lateral directions thereof. The bus bar 16d couples the external terminals 23 of the capacitor cells 2 attached to the different metallic plates 3 and adjacent to each other in the longitudinal directions thereof.

As illustrated in FIG. 8, the capacitor cells 2 are coupled in a zigzag pattern by using the bus bars 16a to 16d and are electrically connected in series. Therefore, it becomes possible to arrange a number of capacitor cells 2 within a limited space. Meanwhile, the two external terminals 23 located on a left upper end and a left lower end in FIG. 8 are outermost electrodes of the capacitor cells 2 connected in series and are connected to outside through wirings W.

The bus bars 16a and 16b are held by a bus bar bracket 17 in a thin plate shape (refer to FIG. 5). The bus bar bracket 17 is composed of a first bracket 171 having openings for holding the bus bars 16a and 16b and a second bracket 172 laminated below the first bracket 171 and having an opening into which the external terminal 23 of the capacitor cell 2 is inserted.

A balance substrate 18 having function to connect the two external terminals 23 of the capacitor cell 2 and to adjust voltage of the capacitor 21 is laminated above the first bracket 171 of the bus bar bracket 17. Meanwhile, it is also possible to separately provide the balance substrate for each capacitor cell 2.

The bus bars 16a to 16d, the bus bar bracket 17 and the balance substrate 18 are arranged above the capacitor cell 2 in a state of being laminated on one another, and are fixed to the capacitor cell 2 by screwing a screw 303 in the external terminals 23.

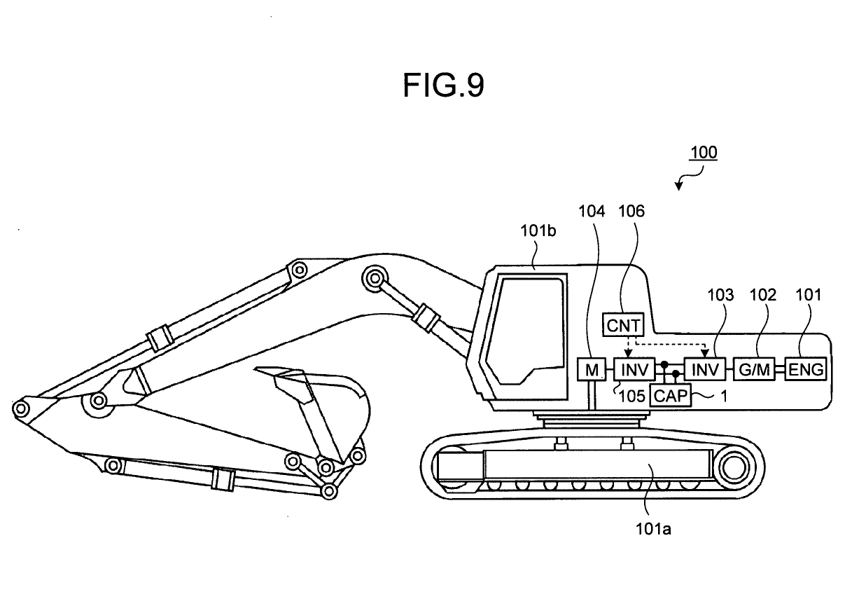

FIG. 9 is a view illustrating a schematic configuration of a hybrid construction machine to which the capacitor module 1 having the above-described configuration is applied. The hybrid construction machine illustrated in the drawing is a hydraulic shovel 100 provided with a self-propelling unit 101a for self propelling by rotation of right and left crawler tracks and the like, and a swing unit 101b having operating machines such as a bucket, a boom and an arm and a driving room and is swingable around a swing axis directed in a predetermined direction relative to the self-propelling unit 101a. Also, the hydraulic shovel 100 is provided with a capacitor module 1, an engine 101 being a driving source, a generator motor 102 having a drive shaft directly connected to a drive shaft of the engine 101, an inverter 103 for driving the generator motor 102, a swing motor 104 having a drive shaft coupled to the swing unit 101b for causing the swing unit 101b to swing around a predetermined axis relative to the self-propelling unit 101a, an inverter 105 for driving the swing motor 104, and a controller 106 for controlling operation of the hydraulic shovel 100. The capacitor module 1 has a function to supply electricity to the generator motor 102 and the swing motor 104 and to store electricity generated by the generator motor 102 and the swing motor 104.

In the hydraulic shovel 100, the cooling water goes through the capacitor module 1 and the inverters 103 and 105. When an output from the cooler first goes through the capacitor module 1, heat dissipation of the capacitor cell 2 of which heat proof temperature is low may be performed by the cooling water of which temperature is the lowest, so that it is preferable.

According to the above-described one embodiment of the invention, it is configured that a plurality of sub modules obtained by attaching a part of the capacitor cells to the metallic plate are formed and the metallic plate of each sub module is fixed to the heat-dissipating body, so that assembling performance may be improved as compared to a case in which the capacitor cell is fixed by the screw passing through the heat-dissipating body.

Also, according to this embodiment, since the cell screw for fixing the capacitor cell does not pass through a space between the cooling medium flow passages, it is not necessary to provide a separate member for insulating the cooling medium flowing through the flow passages from the cell screw. Therefore, a manufacturing cost of the capacitor module may be reduced.

Meanwhile, although a case in which the capacitor module 1 has 120 capacitor cells 2 is illustrated in this embodiment, this is merely an example and the number and a way of arranging the capacitor cells 2 may be appropriately changed.

Also, the number of the capacitor cells and the number of insulating sheets to be fixed to one metallic plate may be appropriately changed.

Also, a casing portion of the capacitor module may be composed by covering the planar heat-dissipating body with the lid having a side wall.

In this manner, the invention may contain various embodiments and the like not herein described, and various design changes and the like may be made without departing from the technical idea specified by recitation in Claims.

### INDUSTRIAL APPLICABILITY

The capacitor module according to the invention is suitable as a storage device for storing electricity generated by the generator motor driven by the engine in the hybrid vehicle equipped with the engine and the generator motor as the driving sources.

1. A capacitor module comprising:
a plurality of capacitor cells each having a capacitor and a capacitor case provided with a first closed-bottomed screw hole on a bottom surface for housing the capacitor;
a metallic cell-fixing body having a through-hole in communication with the first screw hole to which each of the capacitor cells is fixed by screwing a cell screw for fixing each of the capacitor cells into the first screw hole through the through-hole;
an insulator being made of a thermally conductive insulating material and installed between the capacitor cells and the cell-fixing body for insulating the capacitor cells from the cell-fixing body;
a metallic heat-dissipating body having a second closed-bottomed screw hole in which a cell-fixing body screw for fixing the cell-fixing body is screwed and having a flow passage for causing a cooling medium to flow on a rear surface side of a surface on which the second screw hole is provided; and
a cover for covering the surface of the heat-dissipating body on which the flow passage is provided.

2. The capacitor module according to claim 1, wherein the number of the second screw hole is smaller than the number of the capacitor cells.

3. The capacitor module according to claim 1, wherein
the cell-fixing body is a plurality of metallic plates each having a planar shape, and
the insulator is a plurality of insulating sheets each of which is thinner than the metallic plates and of which number is the same as or larger than the number of the metallic plates.

4. The capacitor module according to claim 3, wherein
each of the insulating sheets has a planar portion interposed between the capacitor cells and the metallic plates, and
a side surface portion arranged between the capacitor cells and the cell-fixing body screw from both ends in a longitudinal direction of the planar portion along side surfaces of the capacitor cells.

5. The capacitor module according to claim 1, wherein
the heat-dissipating body has a planar base portion provided with the second screw hole and the flow passage, and
a side wall portion installed so as to be substantially orthogonal to the base portion from a peripheral edge of a surface of the base portion provided with the second screw hole to enclose the side surfaces of the capacitor cells.

6. The capacitor module according to claim 1, comprising:
a screw insulator installed between the cell screw and the cell-fixing body for insulating the cell screw from the cell-fixing body.
